(19) United States
(12) Patent Application Publication
(10) Pub. No.: US 2026/0197938 A1
(43) Pub. Date: Jul. 9, 2026

(54) Component Carrier with Different Line Spacing in Metal Traces, and Manufacture Method

(71) Applicant: AT&S Austria Technologie & Systemtechnik Aktiengesellschaft, Leoben (AT)

(72) Inventors: Jeesoo MOK, Leoben (AT); Artan BAFTIRI, Graz (AT)

(21) Appl. No.: 19/133,207

(22) PCT Filed: Nov. 27, 2023
(86) PCT No.: PCT/EP2023/083151

§ 371 Date: May 27, 2025

(30) Foreign Application Priority Data
Nov. 28, 2022 (CN) 202211503277.7

(51) Int. Cl. H05K 1/02

(52) U.S. Cl. CPC H05K 1/0298

(57) ABSTRACT

A component carrier, including a stack with i) at least one electrically insulating layer structure; ii) a plurality of first electrically conductive traces in and/or on the at least one electrically insulating layer structure, and including a first line spacing; and iii) a plurality of second electrically conductive traces in and/or on the at least one electrically insulating layer structure, and including a second line spacing. The second line spacing is larger than the first line spacing, and a first surface of at least one first electrically conductive trace is smoother or rougher than a second surface of at least one second electrically conductive trace.

### CROSS REFERENCE TO RELATED APPLICATIONS

This application is a national stage application, filed under 35 U.S.C. § 371, of International Patent Application No. PCT/EP2023/083151, filed on Nov. 27, 2023, claiming priority of the filing date of the patent application No. 202211503277.7, filed on Nov. 28, 2022, with the China National Intellectual Property Administration, the disclosures of which are hereby incorporated by reference herein in their entirety.

### TECHNICAL FIELD

The disclosure relates to a component carrier with a stack that comprises a plurality of first electrically conductive traces with first line spacing and a plurality of second electrically conductive traces with a second line spacing. Further, the disclosure relates to a method of manufacturing said component carrier. Additionally, the disclosure relates to the use of such a component carrier.

Accordingly, the disclosure may relate to the technical field of component carriers such as printed circuit boards or IC substrates.

### TECHNICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, an efficient protection against electromagnetic interference (EMI) becomes an increasing issue. At the same time, component carriers shall be mechanically robust and electrically and magnetically reliable so as to be operable even under harsh conditions.

In particular, providing a component carrier with a metal trace high-density pattern may be considered a challenge. A general parameter to quantify a high-density pattern may be the line spacing (L/S), i.e. the compared lengths of metal traces and the dielectric material portions between adjacent traces. The smaller the line spacing, the higher the density of a metal trace pattern may be. In an example, an L/S of 12/12 μm or lower may be technically advantageous, for example with respect to miniaturization and (signal) transmission quality.

While methods such as semi-additive processes (SAP) or modified semi-additive processes (mSAP) may provide a higher density pattern (line spacing) than a subtractive process, the latter may be much more economic and realizable with less effort.

### SUMMARY

There may be a need to provide a component carrier with a high-density pattern in a reliable and economic manner.

A component carrier, a manufacturing method, and a specific use are described.

According to an embodiment of the disclosure, there is described a component carrier comprising a stack with: i) at least one electrically insulating layer structure; ii) a (first) plurality of first electrically conductive traces in and/or on the at least one electrically insulating layer structure and comprising a first line spacing; and iii) a (second) plurality of second electrically conductive traces in and/or on the at least one electrically insulating layer structure and comprising a second line spacing. The second line spacing is larger than the first line spacing, and a first surface of at least one first electrically conductive trace is different (in particular smoother (this feature may reflect a manufacturing step of using an ULP foil) or rougher) than a second surface of at least one second electrically conductive trace.

According to a further embodiment of the disclosure, there is described a method of manufacturing a component carrier, the method comprising: i) forming a stack comprising at least one electrically insulating layer structure; ii) forming a plurality of first electrically conductive traces in and/or on the stack, comprising a first line spacing; and iii) forming a plurality of second electrically conductive traces in and/or on the stack, comprising a second line spacing. The second line spacing is larger than the first line spacing, and a first surface of at least one first electrically conductive trace is smoother or rougher than a second surface of at least one second electrically conductive trace.

According to a further embodiment of the disclosure, there is described a use (method of using) of a plurality of first electrically conductive traces in a component carrier as described above, wherein said first conductive traces have a smoother surface and a lower line spacing than the second electrically conductive traces of the component carrier; and guiding signals with a frequency of at least 6 GHz in and/or on the component carrier.

### Overview of Embodiments

In the context of the present document, the term “metal trace” may refer to an electrically conductive structure that comprises a metal, in particular copper. In particular, a metal trace may be configured as an elongated (preferably in the horizontal direction) electrically conductive structure that may serve for the transmission of signals, in particular high-frequency signals and/or high-speed signals. Additionally or alternatively, the metal trace may conduct electric current, in particular current in the range of 1 pA-1000 A. Further, a metal trace with a rough surface may establish an adhesion with dielectric material, thereby enhancing the stability of a component carrier. A metal trace may have for example a shape of an elongated trace, an annular ring or may be configured as a pad or block. Sidewalls of the metal traces can be straight or inclined/curved.

In the present context, the term “line spacing (L/S)” may in particular refer to a parameter that may be used to quantify the density of a metal trace pattern. While a high L/S ratio may indicate a low-density pattern, a low L/S ratio (e.g. 15/15 μm or less, 12/12 μm or less, 10/10 μm or less) may indicate a high-density pattern. When evaluating the L/S ratio, the component carrier may be seen in top view or in cross section and the metal traces may be considered as lines while the dielectric component carrier material between the lines may be seen as spaces. In general, the length of the lines and the length of the spaces are equal. Nevertheless, there may be examples, wherein L and S are not equal, but one is larger than the other, for example 9/12 or 14/17 in substrate technology.

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, a metal core substrate, an inorganic substrate and an IC (integrated circuit) substrate. A component carrier may also be a hybrid board combining different ones of the above-mentioned types of component carriers.

In the context of the present document, the term “high speed” may refer to digital technology which transmits data at a very high rate (related to time domain). In the context of the present document, the term “high frequency” may in particular refer to the radio frequency of an analog signal at high frequency moving energy (which is related to how electromagnetic wave respond in a specific frequency or range of frequency). However, there may also be a fundamental relationship between high-speed (digital) signals and high-frequency techniques. For example, pulses for digital information transmission are generated by RF waveforms. Basically, a sine wave can be thought of as an RF waveform. When several sine waves of different frequencies are combined, they can form a square wave, and a square wave can generate a pulse of a digital signal. As a simple example, the 2 GB/s digital pulse speed (clock speed) is formed by RF signals at frequency of about 1 GHZ, 3 GHZ, 5 GHZ, 7 GHZ, etc., sorted by a given frequency, respectively, at the fundamental frequency (1 GHZ), the fundamental frequency three times harmonic (3 GHz), five times harmonic (5 GHZ) and seven times harmonic (7 GHZ) frequency.

In the context of the present document, the term “surface roughness” may in particular refer to a property of a metal trace surface, e.g. a sidewall portion property and/or a top portion property. The surface roughness may be seen as a relative term, for example the roughness of a first metal trace is high in comparison to the surface roughness of a second metal trace with a lower roughness. In a further example, surface roughness may be seen as an absolute term, e.g. given as Ra. In a specific example, a rough surface may comprise a surface roughness Ra of more than 500 nm, in particular more than 700 nm. In a further specific example, the smooth surface may comprise a surface roughness Ra of less than 500 nm, in particular less than 300 nm, more in particular less than 100 nm.

According to an embodiment, a rough surface comprises a surface roughness (Ra) of more than 500 nm, in particular more than 700 nm. Additionally or alternatively, a smooth surface comprises a surface roughness (Ra) of less than 500 nm, in particular less than 300 nm, more in particular less than 100 nm.

The “roughness of” a surface quantifies the extent to which the surface deviates from its ideal form. Any deviations are usually analyzed in direction of the normal vector of the surface and are characterized by an amplitude, i.e. the height or length of the deviations in surface normal direction, and by a frequency, denoting the amount or number of deviations per surface area. Surface roughness correlates with friction between interacting rough surfaces, if they are moved relative to each other.

According to an example embodiment, the disclosure may be based on the idea that a component carrier with a high-density pattern may be provided in a reliable and economic manner, when a plurality of first electrically conductive traces and a plurality of second electrically conductive traces are formed in/on the same stack, yet comprising a different line spacing, in particular also a different surface roughness.

Conventionally, metal traces are either produced with a high-density pattern for specific applications (e.g. signal transmission) in a costly manner, or with a low-density pattern for lower performance applications in an economic manner.

However, the inventors did now surprisingly find that a combination of both advantages can be enabled in a straightforward manner. In one and the same component carrier, there may be provided metal traces for different purposes/functionalities. For example, a plurality of first metal traces that should be used for a high-performance application may be manufactured with a focus on a high-density pattern, thereby using, for example, an mSAP process. In a further example, a plurality of second metal traces, in the same stack, should be used merely for transporting current and/or heat. In this case, no high-density pattern is necessary and an economic subtractive process may be applied for patterning. In other words, the metal traces of one component carrier may be manufactured with different methods/approaches depending on the desired functionality, thereby maximizing efficiency and minimizing costs.

In a preferred example, the plurality of first metal traces may be manufactured from a (low-profile) metal foil, which may lead to an especially smooth surface of said first metal traces. It has been found by the inventors that such a (ultra-thin profile) foil may be patterned by an economic subtractive process, thereby surprisingly achieving an especially advantageous high-density pattern. In particular, the low roughness at the bottom of the metal layer may enable a more efficient (more accurate, faster) etching process than in case of a high roughness.

### Description of Example Embodiments

According to an embodiment, the plurality of first electrically conductive traces and the plurality of second electrically conductive traces are arranged one above the other (in particular with at least one electrically insulating material in between) along the vertical height (z) of the stack. This may provide the advantage that within the same layer stack, different functionalities may be realized in an economic and straightforward manner. While the traces with the higher density may be used e.g. for signal transmission, where finer patterns may be advantageous, the traces with the lower density may be used for current transmission only, for example.

In an example (see e.g. FIGS. 6G and 7G), the component carrier may comprise a plurality of electrically conductive traces arranged at different vertical levels. These traces may serve as well for different purposes. Additionally, electric interconnections may be enabled by one or more (through) vias.

According to a further example, a first sidewall of at least one (in particular all sidewalls of a metal trace in a horizontal (x, y) direction) first/second electrically conductive trace is inclined, in particular curved. In an example, said first/second electrically conductive trace comprises a trapezoidal or frustoconical shape.

In a specific example, all the first/second electrically conductive traces may comprise this feature, preferably those on the same surface of the stack and/or those on the same thickness position. This feature may reflect a manufacture step that comprises a subtractive process.

In a subtractive process, a thick metal layer may be provided (in particular a metal foil is thickened by plating further metal on the foil to thereby provide the thick metal layer) and is partially protected by a mask of photoresist or dry film resist. Areas not protected will be removed, e.g. using an etchant. Due to an under-etch between the top region of the metal trace under production and the mask, a subtractive process generally leads to inclined/curved sidewalls.

Generally, it may be said that the density (referring to line spacing, 30/30 μm may be considered as a lower limit in an example) achievable by a subtractive process is lower than for an (m) SAP process (here 25/25 μm or even 5/5 μm may be considered as the lower limit in an example). However, a subtractive process may save costs and efforts compared to the other processes, thereby it may be significantly more economic.

According to a further example, a further first/second sidewall of at least one first/second electrically conductive trace is straight, in particular wherein said first electrically conductive trace comprises a rectangular shape. In a specific example, all the first/second electrically conductive traces may comprise this feature, preferably those on the same surface of the stack and/or those on the same thickness position.

This feature may reflect a manufacturing step that comprises a SAP or an mSAP manufacture process (and/or exclude a subtractive manufacturing process).

In a semi-additive process, the mask (protection layer), e.g. photoresist or dry film resist, is provided on a thin metal layer. Then, plating is performed, so that regions, which are not protected by the mask, are filled with metal, thereby forming the metal traces. Afterwards, the mask is removed, and a step of flash etching may be performed to remove the residues of the thin metal layer adjacent to the metal trace. While the semi-additive process starts with a thin metal layer that has been formed on dielectric material in an electroless manner (e.g. by sputtering), the modified semi-additive process may start with an ultra-thin metal foil that is already attached to the dielectric material.

As discussed above, (m) SAP is generally considered to perform significantly better with respect to high density patterns than the subtractive methods. Nevertheless, the costs and efforts of (m) SAP may be higher, so that these methods may be seen as less economic.

According to a further example, the height (h2) of the plurality of second electrically conductive traces is larger or smaller than the height (h1) of the plurality of first electrically conductive traces. Different heights (along z direction) may reflect different manufacturing methods and/or different metal layer (before forming the traces) thicknesses. Hence, not only the density (line spacing) of the traces (in different vertical levels) may be different but also the height of the metal traces. Accordingly, the length/width (along the x, y directions) of the first traces and the second traces may be different. This may provide the advantage that different functionalities may be realized in an easy manner at different levels of the component carrier.

According to a further example, the first (or second) line spacing is 12/12 μm or smaller, in particular 10/10 μm or smaller, more in particular 8/8 μm or smaller. Hence, a desired high-density pattern may be realized in an economic manner. For example, by using an ULP foil (see below), in the manufacturing process, such a small L/S may be achieved in an economic manner using a subtractive manufacture process.

According to a further example, the plurality of first electrically conductive traces is manufactured from an ultra-low profile (ULP) foil. In the context of this document, an ULP foil made be a metal (in particular copper) foil that may be extremely thin, i.e. 100 μm or loss, in particular 50 μm or less, in particular 10 μm or less, more in particular 5 μm or less. In an example, such a foil comprises an ultra-low profile and hence a smooth surface. Accordingly, metal traces formed by patterning such an ULP foil, may comprise smooth surfaces as well, thereby reflecting the manufacturing step of using the ULP foil. In an example, the average roughness Rz (difference between the tallest peak and the deepest valley) of the ULP foil may be 10 μm or less, in particular 5 μm or less, more in particular 3 μm or less, more in particular 2 μm or less. In a specific example, Rz may be in the range 0.25 μm to 2 μm. Due to the extremely low profile (high smoothness), it may be enabled to perform an especially efficient subtractive process that leads to a surprisingly low line spacing. In a specific example, the ULP foil is, however, (slightly) roughened to improve adhesion to an electrically insulating layer structure.

According to a further example, the plurality of first and/or second electrically conductive traces is formed on, in particular directly on, the at least one electrically insulating layer structure. The latter may hereby serve as a mounting base to enable an efficient and reliable patterning process. In an example, the plurality of first and/or second electrically conductive traces may be, after patterning, pressed (and thereby embedded) into the electrically insulating layer structure prepreg material. This may provide the advantage that the traces may be well protected by the insulating material.

According to a further example, the plurality of first electrically conductive traces is formed in (pressed in), in particular embedded in, a top portion of the at least one electrically insulating layer structure, in particular wherein the electrically insulating layer structure comprises a prepreg. As described above, the first electrically conductive traces are embedded in an accurate and robust manner when being pressed into a prepreg material.

According to a further example, the component carrier further comprises at least one dielectric layer structure formed on top of the embedded plurality of first and/or second electrically conductive traces. Such a dielectric layer structure may be directly laminated onto the (embedded) first and/or second electrically conductive traces to thereby perform a component carrier layer build-up. In one example, a further prepreg layer is used as the dielectric layer structure. Yet, in another example, the dielectric layer structure may be free of fibers, for example an Ajinomoto build-up film (ABF)®, that may comprise spheres as filler particles instead. Ajinomoto build up film (ABF) is a registered mark of the Ajinomoto Co., Inc. of Tokyo, Japan. The latter may introduce an especially advantageous flexibility into the component carrier.

According to a further example, the plurality of second electrically conductive traces is formed in, in particular embedded in, in particular at the bottom of, the at least one electrically insulating layer structure.

In the context of this document, the terms “top” and “bottom” may be seen as the two main surfaces of a component carrier (these are parallel to the directions of main extension, i.e. x and y), which are opposite to each other.

In an example, the second electrically conductive layer structures may be formed/embedded on/in the electrically insulating layer structure using a conventional process such as a subtractive one. Afterwards, the first electrically conductive traces may be formed on the opposed side by the new approach described in this document.

According to a further example, the component carrier further comprises a further electrically insulating layer structure on top of the at least one electrically insulating layer structure, in particular thereby embedding the first and/or the second electrically conductive traces. Such a further electrically insulating layer structure may be directly laminated onto the (embedded) first and/or second electrically conductive traces to thereby perform a component carrier layer build-up. In one example, a further prepreg layer is used.

According to a further example, the component carrier further comprises a via, formed at least partially through the stack, and electrically connecting at least one first electrically conductive trace and at least one second electrically conductive trace. In the context of this document, the term “via” may refer to a vertical interconnection access, i.e. an electrical/thermal connection between different levels in the vertical direction of the stack/component carrier. The via may be for example a buried via, a through via, a completely filled via, a partially filled via, or a plated through hole. The via may be fully or partially filled with electrically conductive material, e.g. copper. Several vias may be stacked in the vertical direction. This may provide the advantage that electrically conductive traces at different vertical levels of the stack may be interconnected. Hence, different functionalities may be efficiently combined.

According to a further example, the method further comprises i) forming an electrically conductive layer, in particular a foil, more in particular an ULP foil, on the at least one electrically insulating layer structure; and ii) patterning the electrically conductive layer, thereby forming the plurality of first electrically conductive traces and/or second electrically conductive traces. The patterning may be performed with established methods such as subtractive, mSAP, SAP, or a combination thereof.

According to a further example, the method further comprises pressing the plurality of first electrically conductive traces and/or second electrically conductive traces at least partially into the at least one electrically insulating layer structure, in particular a prepreg, to thereby embed the plurality of first electrically conductive traces in the electrically insulating layer structure (see above).

According to a further example of the method, forming the plurality of first electrically conductive traces comprises at least one of a subtractive process, a semi-additive process, a modified semi-additive process. This may provide the advantage that, based on the desired results, established and highly efficient manufacturing methods may be directly applied. This enables a high flexibility with respect to the manufacturing process. While for some functionalities a high density may be preferred, another functionality may be realized in an economic manner. Also, a combination of both considerations may be possible.

According to a further embodiment, HF signals guided through the first/second electrically conductive traces may comprise a frequency of at least 6 GHZ, in particular at least 28 GHz. This may provide the advantage that signals in the high-frequency range may be transmitted (in particular via the second metal traces) in an accurate and reliable manner.

According to a further embodiment, at least one portion (in particular on top of a via connection) of the first electrically conductive trace has a different, in particular larger, height compared to other portions of the first electrically conductive trace.

According to a further embodiment, said portion of the first electrically conductive traces comprise a step-shaped structure (L-like structure), in particular at a sidewall portion.

According to a further embodiment, said portions of the first electrically conductive traces comprise a smooth surface portion and/or a rough surface portion. In particular, a top surface of said portion may be rough, while the sidewall portion (in particular the step-shaped structure) comprises a smooth surface. In an embodiment, the smooth surface may result from the ULP foil, while the rough surface may result from plating.

In an embodiment, the component carrier is configured as one of the group consisting of a printed circuit board, a substrate (in particular an IC substrate), and an interposer.

In an embodiment, the component carrier is shaped as a plate. This contributes to the compact design, wherein the component carrier nevertheless provides a large basis for mounting components thereon. Furthermore, in particular a naked die as an example of an embedded electronic component, can be conveniently embedded, thanks to its small thickness, into a thin plate such as a printed circuit board.

In an embodiment, the component carrier stack comprises at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). In another embodiment, the substrate may be substantially larger than the assigned component (for instance in a flip chip ball grid array, FCBGA, configuration). More specifically, a substrate can be understood as a carrier for electrical connections or electrical networks as well as a component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten, magnesium, carbon, (in particular doped) silicon, titanium, and platinum. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one further component may be embedded in and/or surface mounted on the stack. The component and/or the at least one further component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs), indium phosphide (InP) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), Electroless Nickel Electroless Palladium Immersion Gold (ENEPIG), gold (in particular hard gold), chemical tin (chemical and electroplated), nickel-gold, nickel-palladium, etc. Also nickel-free materials for a surface finish may be used, in particular for high-speed applications. Examples are ISIG (Immersion Silver Immersion Gold), and EPAG (Electroless Palladium Autocatalytic Gold).

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1 shows a component carrier according to an example embodiment of the disclosure.

FIG. 2 shows a cross-section through a metal trace with straight sidewalls manufactured according to an example embodiment of the disclosure.

FIG. 3 shows a cross-section through a metal trace with inclined sidewalls manufactured according to an example embodiment of the disclosure.

FIG. 4A shows a metal trace with a smooth surface, while FIG. 4B shows a metal trace with a rough surface, according to example embodiments of the disclosure.

FIG. 5 shows a cross-section through metal traces with straight sidewalls and metal traces with inclined surfaces according to an example embodiment of the disclosure.

FIG. 6A, FIG. 6B, FIG. 6C, FIG. 6D, FIG. 6E, FIG. 6F, and FIG. 6G show a manufacturing method of a component carrier according to an example embodiment of the disclosure.

FIG. 7A, FIG. 7B, FIG. 7C, FIG. 7D, FIG. 7E, FIG. 7F, and FIG. 7G show a manufacturing method of a component carrier according to a further example embodiment of the disclosure.

### DETAILED DESCRIPTION OF THE ILLUSTRATED EMBODIMENTS

The illustrations in the drawings are schematically presented. In different drawings, similar or identical elements are provided with the same reference signs.

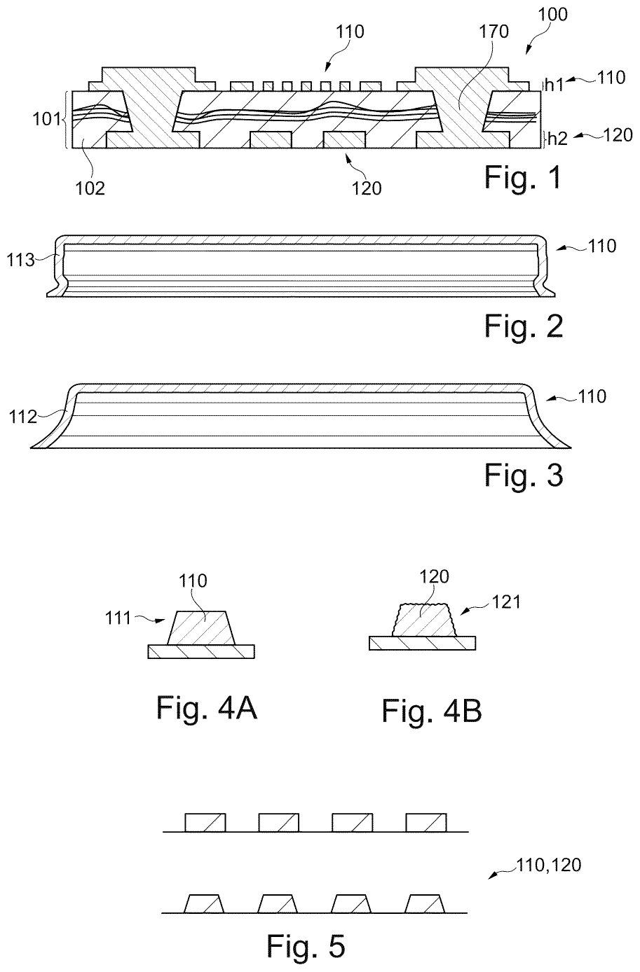

FIG. 1 shows a component carrier 100 according to an example embodiment of the disclosure, comprising a stack 101 with a massive electrically insulating layer structure 102 of prepreg. On top of said electrically insulating layer structure 102, there is arranged a plurality of first electrically conductive traces 110 comprising a first (small) line spacing (e.g. 12/12 μm or smaller, in particular 10/10 μm or smaller) and a first height h1. At the bottom of and embedded in the electrically insulating layer structure 102, there is formed a plurality of second electrically conductive traces 120, comprising a second (large) line spacing and a second height h2. It can be seen that the second line spacing is larger than the first line spacing, and the second height h2 is larger than the first height h1. Additionally, a first surface 111 of the first electrically conductive traces can be smoother or rougher than a second surface 121 of the second electrically conductive traces 120 (not shown in FIG. 1, see FIGS. 4A and 4B). Such a smooth surface 111 reflects a manufacture step of using a metal foil with a very low profile (roughness) for providing the metal traces by patterning.

Above the via 170, the first electrically conductive traces 110 comprises a portion that is larger (higher) than other portions of the first electrically conductive traces 110. At the sidewalls said portion is step-shaped (L-shaped). In a specific embodiment, the sidewalls can comprise a rough surface.

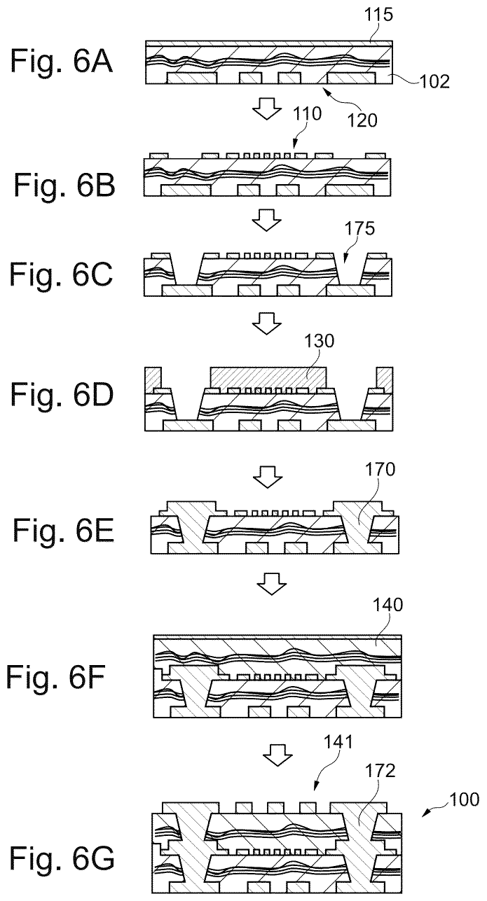

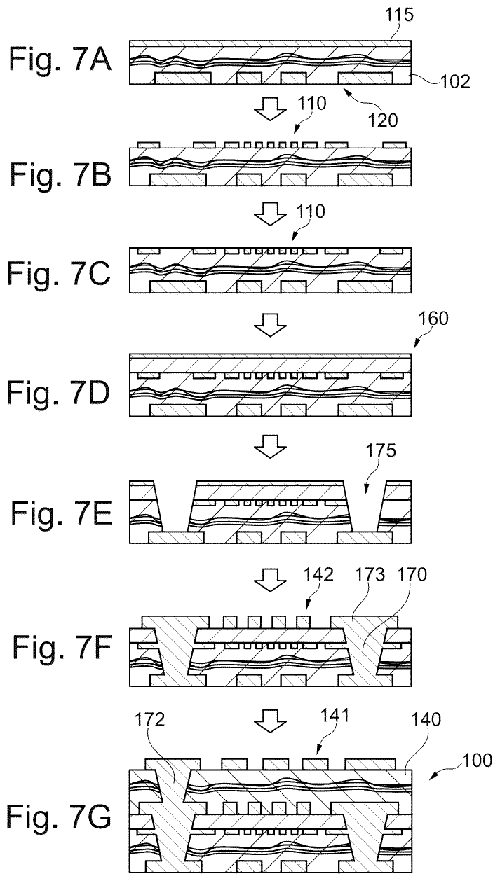

The plurality of first electrically conductive traces 110 have been manufactured from an ultra-low profile (ULP) foil 115, which is described in detail in FIGS. 6 and 7. Since the UPC foil comprises a smooth surface, smooth sidewalls 111 of the first electrically conductive traces 110 can reflect a manufacture step of using the ULP foil. However, in embodiment, the (inclined) sidewalls of the ULP foil can also be rough, for example due to an etching process.

FIG. 2 shows a cross-section through a metal trace 110 with straight sidewalls (rectangular shape) 113 manufactured according to an example embodiment of the disclosure. Such a metal trace shape is generally obtained by a (modified) semi-additive manufacturing process.

FIG. 3 shows a cross-section through a metal trace 110 with inclined sidewalls (trapezoidal shape) 112 manufactured according to a further example embodiment of the disclosure. It can be seen in the cross-section that the sidewalls 112 are curved, i.e. being wider at the bottom than at the top of the metal trace 110. Such a metal trace shape is generally obtained by a subtractive manufacture process. The curved shape is caused by so-called under-etching, when an etchant reacts between copper material of the metal trace and a mask on top of the metal layer to be etched.

FIG. 4A shows a first metal trace 110 with a smooth surface 111 (a detailed image obtained by an electron microscope is shown), while FIG. 4B shows a second metal trace 120 with a rough surface 121 (again a detailed image obtained by an electron microscope is shown), according to example embodiments of the disclosure.

FIG. 5 shows a cross-section through metal traces 110, 120 with straight sidewalls (see also FIG. 2) and metal traces 110, 120 with inclined sidewalls (see also FIG. 3) according to an example embodiment of the disclosure.

FIG. 6A, FIG. 6B, FIG. 6C, FIG. 6D, FIG. 6E, FIG. 6F, and FIG. 6G show a manufacturing method of a component carrier 100 according to an example embodiment of the disclosure.

In FIG. 6A there is provided a component carrier preform with a stack that comprises an electrically insulating layer structure 102 made of prepreg (the fibers, e.g. glass fibers, are schematically shown). At the bottom of the electrically insulating layer structure 102, a plurality of second electrically conductive traces 120 are embedded. An electrically conductive layer 115 is formed on the electrically insulating layer structure 102, thereby on top of the stack. Specifically, the electrically conductive layer 115 is a foil, more specifically an ULP copper foil.

In FIG. 6B the electrically conductive layer 115 is patterned using a subtractive process (e.g, etching), thereby forming the plurality of first electrically conductive traces 110.

In FIG. 6C holes 175 are drilled through a part of the first electrically conductive traces 110, and the electrically insulating layer structure 102, down to the embedded second electrically conductive traces 110.

In FIG. 6D a protection layer structure 130 (e.g. DFR, dry film resist) is formed (electroless, e.g. sputtering and/or chemically) on top of the first electrically conductive traces 110.

In FIG. 6E the holes 175 are filled with metal (e.g by plating) to thereby provide metal-filled through vias 170 that electrically connect the first electrically conductive traces 110 on top of the stack with the second electrically conductive traces 120 at the bottom of the stack. The protection layer structure 130 has been removed afterwards.

In FIG. 6F a further electrically insulating layer structure 140 (e.g. prepreg) is formed (laminated) on top of the at least one electrically insulating layer structure 102, thereby embedding the first electrically conductive layer structure 110 at the bottom of the further electrically insulating layer structure 140.

In FIG. 6G a plurality of further electrically conductive traces 141 with a further line spacing (comparable to the line spacing of the second electrically conductive traces 120) is formed by a subtractive process on top of the further electrically insulating layer structure 140. Further vias 172 are provided (e.g. as described in FIGS. 6D and 6E) through part of the further electrically conductive traces 141 to electrically interconnect all three electrically conductive traces 110, 120, 141. In the vertical direction, two tapering vias 170, 172 are stacked to provide the through connection. A final component carrier 100 is obtained in this manner. Additionally, a surface finish may be applied, e.g. ENIPIG or solder resist (not shown in the Figure).

FIG. 7A, FIG. 7B, FIG. 7C, FIG. 7D, FIG. 7E, FIG. 7F, and FIG. 7G show a manufacturing method of a component carrier 100 according to a further example embodiment of the disclosure.

In FIG. 7A there is provided a component carrier preform with a stack that comprises an electrically insulating layer structure 102 of prepreg (the fibers, e.g. glass fibers, are schematically shown). At the bottom of the electrically insulating layer structure 102, a plurality of second electrically conductive traces 120 are embedded. An electrically conductive layer 115 (see above) is formed on the electrically insulating layer structure 102, on top of the stack. Specifically, the electrically conductive layer 115 is a foil.

In FIG. 7B the electrically conductive layer 115 is patterned using a subtractive process, thereby forming the plurality of first electrically conductive traces 110.

In FIG. 7C the plurality of first electrically conductive traces 110 are pressed into the electrically insulating layer structure 102 (as the prepreg is not fully cured), to thereby embed the plurality of first electrically conductive traces 110 in the electrically insulating layer structure 102 (top portion).

In FIG. 7D a dielectric layer structure 160 (e.g. an ABF® layer) is formed (laminated) on top of the embedded plurality of first electrically conductive traces 110 as a protection layer. ABF is a registered mark of the Ajinomoto Co., Inc. of Tokyo, Japan.

In FIG. 7E holes 175 are drilled through the electrically insulating layer structure 102 down to the embedded second electrically conductive traces 120.

In FIG. 7F a plurality of other electrically conductive traces 142 with a further line spacing (comparable to the line spacing of the second electrically conductive traces 120) is formed by an mSAP process or a subtractive process on top of the dielectric layer structure 160 (after removing a dielectric layer structure 160 protection layer). The holes 175 are filled with metal to thereby provide metal-filled through vias 170, 173 that electrically connect the first electrically conductive traces 110 with other electrically conductive traces 142 and the embedded second electrically conductive traces 120.

In FIG. 7G a further electrically insulating layer structure 140 is formed on top of the other electrically conductive traces 142, thereby embedding the latter. A further via 172 is provided through the further electrically insulating layer structure 140 to contact one of the vias 170. Further electrically conductive traces 141 are formed on top of the further electrically insulating layer structure 140 using a subtractive process. The vertically stacked vias 170, 172 now through-connect the further electrically conductive traces 141, the other electrically conductive traces 142, the first electrically conductive traces 110, and the second electrically conductive traces 120. A final component carrier 100 is obtained in this manner.

### REFERENCE NUMERALS

100 Component carrier
101 Stack
102 Electrically insulating layer structure
110 Plurality of first electrically conductive traces
111 First surface
112 First sidewall
113 Further first sidewall
115 Electrically conductive layer
120 Plurality of second electrically conductive traces
121 Second surface
130 Protection layer structure
140 Further electrically insulating layer structure
141 Plurality of further electrically conductive traces
142 Plurality of other electrically conductive traces
160 Dielectric layer structure
170 Via
172 Second via
173 Third via
175 Hole

1. A component carrier, comprising a stack with:
at least one electrically insulating layer structure;
a plurality of first electrically conductive traces in and/or on the at least one electrically insulating layer structure, and comprising a first line spacing; and
a plurality of second electrically conductive traces in and/or on the at least one electrically insulating layer structure, and comprising a second line spacing;
wherein the second line spacing is larger than the first line spacing, and
wherein a first surface of at least one first electrically conductive trace is smoother or rougher than a second surface of at least one second electrically conductive trace.

2. The component carrier according to claim 1,
wherein the plurality of first electrically conductive traces and the plurality of second electrically conductive traces are arranged one above the other along the vertical height of the stack.

3. The component carrier according to any one of the preceding claim 1,
wherein a first sidewall of at least one first electrically conductive trace is inclined, in particular curved.

4. The component carrier according to claim 1,
wherein a further first sidewall of at least one first electrically conductive trace is straight.

5. The component carrier according to claim 1,
wherein the height of the plurality of second electrically conductive traces is larger or smaller than the height of the plurality of first electrically conductive traces.

6. The component carrier according to claim 1,
wherein the first line spacing is 12/12 μm or smaller.

7. The component carrier according to claim 1,
wherein the plurality of first electrically conductive traces is manufactured from an ultra-low profile.

8. The component carrier according to claim 1,
wherein the plurality of first electrically conductive traces and/or the plurality of second electrically conductive traces is formed on the at least one electrically insulating layer structure.

9. The component carrier according to claim 1,
wherein the plurality of first electrically conductive traces is embedded in a top portion of the at least one electrically insulating layer structure wherein the electrically insulating layer structure comprises a prepreg.

10. The component carrier according to claim 9, further comprising:
at least one dielectric layer structure formed on top of the embedded plurality of first electrically conductive traces and/or the plurality of second electrically conductive traces.

11. The component carrier according to claim 1,
wherein the plurality of second electrically conductive traces is formed in the at least one electrically insulating layer structure.

12. The component carrier according to claim 1,
further comprising:
a further electrically insulating layer structure on top of the at least one electrically insulating layer structure, the plurality of first electrically conductive traces (110) or the plurality of second electrically conductive traces embedded in at least one electrically insulating layer structure.

13. The component carrier according to claim 1,
further comprising:
a via, formed at least partially through the stack, and electrically connecting at least one first electrically conductive trace and at least one second electrically conductive trace.

14. A method of manufacturing a component carrier, the method comprising:
forming a stack comprising at least one electrically insulating layer structure;
forming a plurality of first electrically conductive traces, comprising a first line spacing, in and/or on the stack; and
forming a plurality of second electrically conductive traces, comprising a second line spacing, in and/or on the stack;
wherein the second line spacing is larger than the first line spacing, and
wherein a first surface of at least one first electrically conductive trace is smoother or rougher than a second surface of at least one second electrically conductive trace.

15. The method according to claim 14, further comprising:
forming an electrically conductive layer on the at least one electrically insulating layer structure; and
patterning the electrically conductive layer, thereby forming the plurality of first electrically conductive traces and/or the plurality of second electrically conductive traces.

16. The method according to claim 15, further comprising:
pressing the plurality of first electrically conductive traces and/or the plurality of second electrically conductive traces at least partially into the at least one electrically insulating layer structure to thereby embed the plurality of first electrically conductive traces in the electrically insulating layer structure.

17. The method according to claim 15,
wherein the electrically conductive layer comprises an ultra-thin profile foil.

18. The method according to claim 14,
wherein forming the plurality of first electrically conductive traces and/or the plurality of second electrically conductive traces comprises a subtractive process and/or a semi-additive process, SAP, and/or a modified semi-additive process, mSAP.

19. A method, comprising:
arranging plurality of first electrically conductive traces with a first line spacing and a plurality of second electrically conductive traces with a second line spacing different from the first line spacing in and/or on a stack of electrically insulating layers in a component carrier, wherein said first conductive traces have a smoother surface and a lower line spacing than the second electrically conductive traces of the component carrier, and
guiding signals with a frequency of at least 6 GHz in and/or on the component carrier.
